(19) United States
(12) Patent Application Publication
(10) Pub. No.: US 2025/0301879 A1
(43) Pub. Date: Sep. 25, 2025

(54) DISPLAY PANEL AND DISPLAY DEVICE

(71) Applicant: Wuhan China Star Optoelectronics Semiconductor Display Technology Co., Ltd., Wuhan, Hubei (CN)

(72) Inventors: Xiang ZUO, Wuhan, Hubei (CN); Xue ZHOU, Wuhan, Hubei (CN)

(21) Appl. No.: 18/861,626

(22) PCT Filed: Jun. 30, 2023
(86) PCT No.: PCT/CN2023/104445

§ 371 Date: Oct. 30, 2024

(30) Foreign Application Priority Data
Nov. 18, 2022 (CN) 202211451146.9

(51) Int. Cl. H10K 59/80; H10K 59/121

(52) U.S. Cl. CPC H10K 59/80515; H10K 59/121

(57) ABSTRACT

The present application discloses a display panel and a display device, wherein the display panel includes a substrate, a first anode, a second anode, a light-emitting layer and a cathode, wherein the second anode includes a flat portion and a recessed portion, and the light-emitting layer is in contact with the recessed portion and at least a portion of the flat portion. The recessed portion can deflect light in a direction of a smaller angle, accelerate the brightness attenuation at a large viewing angle. When the white light is finally synthesized, an abnormal color shift will occur, resulting in distortion, thereby achieving the anti-peep effect while improving the light emission efficiency of the display panel.

### TECHNICAL FIELD

The present disclosure relates to the field of display technology, and in particular to a display panel and a display device.

### BACKGROUND

Display technology of organic light-emitting diodes (OLEDs) has the advantages of high luminous efficiency, fast response speed, the ability to be fabricated on flexible substrates, good bending resistance, and wide viewing angle, and is favored by a large number of users. With the advancement of technology and the improvement of people's living standards, the production technology of display panels is becoming increasingly mature, and the requirements for power consumption of the display panels are increasing in the market. Additionally, in the commercial field, the anti-peep performance of display panels is gradually becoming a focus of users' attention.

### SUMMARY

At present, most of the anti-peep measures on the market adopt the form of pasting an anti-peep film on the outermost layer of the display panel. Although this can play a role in anti-peep, it also increases the overall thickness of the screen and reduces the light emission efficiency at the positive viewing angle, so that electronic products have certain limitations in the operation process.

In summary, existing display panels with an anti-peep function have the problem of low light emission efficiency. Therefore, it is necessary to provide a display panel and a display device to improve this defect.

Embodiments of the present application provide a display panel and a display device, which can improve the light emission efficiency of the display panel while achieving an anti-peep effect.

An embodiment of the present application provides a display panel comprising a plurality of main pixel regions and a plurality of auxiliary pixel regions, wherein the main pixel region is adjacent to the auxiliary pixel region, and the display panel further comprises:
a substrate;
a plurality of first anodes disposed on the substrate, the first anodes being located in the main pixel regions;
a plurality of second anodes disposed on the substrate, the second anodes being located in the auxiliary pixel regions, the second anode including a flat portion and a recessed portion, and the recessed portion being connected to the flat portion;
a light-emitting layer disposed on a side of the first anodes and the second anode away from the substrate, the light-emitting layer being in contact with the first anodes, and the light-emitting layer being in contact with the recessed portion and at least a part of the flat portion; and
a cathode disposed on a side of the light-emitting layer away from the substrate.

According to an embodiment of the present application, the display panel includes an anti-peep mode and a normal display mode;
when the display panel is in the anti-peep mode, at least a part of the auxiliary pixel regions and the corresponding main pixel regions emit light simultaneously; and
when the display panel is in the normal display mode, the auxiliary pixel regions does not emit light.

According to an embodiment of the present application, the display panel comprises a first pixel driving circuit electrically connected to the first anodes, and a second pixel driving circuit electrically connected to the second anodes,
wherein the first pixel driving circuit is an active matrix circuit, and the second pixel driving circuit is an active matrix circuit or a passive matrix circuit.

According to an embodiment of the present application, the display panel includes a flat layer, and the flat layer is disposed between the second anodes and the substrate;
wherein a side of the flat layer away from the substrate is provided with grooves, the flat portion is laid on a periphery of the groove, and the recessed portion is laid on a surface of the groove.

According to an embodiment of the present application, the flat layer includes a first flat layer and a second flat layer, and the second flat layer is disposed on a side of the first flat layer away from the substrate;
wherein the groove is recessed into the second flat layer from a side surface of the second flat layer away from the substrate, and a thickness of the groove is less than or equal to a thickness of the second flat layer.

According to an embodiment of the present application, the recessed portion has an inclined portion and a bottom portion, and an angle between the inclined portion and a plane, on which the bottom portion is located, is between 20 degrees and 60 degrees.

According to an embodiment of the present application, the display panel further includes a pixel definition layer, and the pixel definition layer is disposed between the anodes and the light-emitting layer;
wherein a plurality of first pixel openings and a plurality of second pixel openings are provided on the pixel definition layer, a portion of the first anode exposed by the first pixel openings is tiled on the substrate, and the second pixel openings expose the recessed portion and at least a portion of the flat portion.

According to an embodiment of the present application, an orthographic projection of the recessed portion on the substrate falls within an orthographic projection of the second pixel opening on the substrate.

According to an embodiment of the present application, the main pixel regions and the auxiliary pixel regions are alternately disposed, and the first anode and the second anode are disposed in a same layer.

According to an embodiment of the present application, the number of the main pixel regions and the number of the auxiliary pixel regions is the same.

An embodiment of the present application further provides a display device including a display panel, which includes a plurality of main pixel regions and a plurality of auxiliary pixel regions, wherein the main pixel region is disposed adjacent to the auxiliary pixel region, and the display panel further comprises:
a substrate;
a plurality of first anodes disposed on the substrate, the first anodes being located in the main pixel regions;
a plurality of second anodes disposed on the substrate, the second anodes being located in the auxiliary pixel regions, the second anode including a flat portion and a recessed portion, and the recessed portion being connected to the flat portion;
a light-emitting layer disposed on a side of the first anodes and the second anode away from the substrate, the light-emitting layer being in contact with the first anodes, and the light-emitting layer being in contact with the recessed portion and at least a part of the flat portion; and
a cathode provided on a side of the light-emitting layer away from the substrate.

According to an embodiment of the present application, the display panel includes an anti-peep mode and a normal display mode;
when the display panel is in the anti-peep mode, at least a part of the auxiliary pixel regions and the corresponding main pixel regions emit light simultaneously; and
when the display panel is in the normal display mode, the auxiliary pixel regions do not emit light.

According to an embodiment of the present application, the display panel includes a first pixel driving circuit electrically connected to the first anodes, and a second pixel driving circuit electrically connected to the second anodes,
wherein the first pixel driving circuit is an active matrix circuit, and the second pixel driving circuit is an active matrix circuit or a passive matrix circuit.

According to an embodiment of the present application, the display panel includes a flat layer, and the flat layer is provided between the second anodes and the substrate;
wherein a side of the flat layer away from the substrate is provided with grooves, the flat portion is laid on a periphery of the groove, and the recessed portion is laid on a surface of the groove.

According to an embodiment of the present application, a width of the groove gradually decreases from one end away from the substrate to one end close to the substrate.

According to an embodiment of the present application, a cross-sectional shape of the groove is an inverted trapezoid.

According to an embodiment of the present application, the flat layer includes a first flat layer and a second flat layer, and the second flat layer is disposed on a side of the first flat layer away from the substrate;
wherein the groove is recessed into the second flat layer from a side surface of the second flat layer away from the substrate, and a thickness of the groove is less than or equal to a thickness of the second flat layer.

According to an embodiment of the present application, the recessed portion has an inclined portion and a bottom portion, and an angle between the inclined portion and a plane, on which the bottom portion is located, is between 20 degrees and 60 degrees.

### BENEFICIAL EFFECTS

Beneficial effects of embodiments of the present application: embodiments of the present application provide a display panel and a display device, wherein the display panel includes a plurality of main pixel regions and a plurality of auxiliary pixel regions, the main pixel region is disposed adjacent to the auxiliary pixel region. The display panel further includes a substrate, a plurality of first anodes, a plurality of second anodes, a light-emitting layer and a cathode. The first anode is located in the main pixel region, and the second anode is located in the auxiliary pixel region. The second anode includes a flat portion and a recessed portion, wherein the flat portion is connected to the recessed portion. The light-emitting layer is disposed on the side of the first anode and the second anode away from the substrate. The first anode is in contact with the light-emitting layer, which is in contact with the recessed portion and at least part of the flat portion. When the display panel is in operation, the main pixel regions can normally emit light, and the recessed portion of the second anode in the auxiliary pixel regions can deflect the light in a direction of smaller angle, which accelerates the brightness attenuation at a large viewing angle. When the white light is finally synthesized, an abnormal color shift will occur, resulting in distortion, thereby achieving the anti-peep effect while improving the light emission efficiency of the display panel.

### BRIEF DESCRIPTION OF THE DRAWINGS

To more clearly illustrate the technical solutions of the present application, a brief introduction to the drawings used in the description of the embodiments will be provided below. It is evident that the drawings described below represent only some embodiments of the present application, and for those skilled in the art, other drawings can be derived from these drawings without creative labor.

FIG. 1 is a schematic diagram of a stacked structure of layers of a first display panel provided by an embodiment of the present application.

FIG. 2 is a schematic diagram of a partial stacked structure of layers of the first display panel provided by the embodiment of the present application.

FIG. 3 is a schematic principle diagram provided by the embodiment of the present application.

FIG. 4 is a schematic diagram of a partial stacked structure of layers of a second display panel provided by an embodiment of the present application.

FIG. 5 is a schematic diagram of a partial stacked structure of layers of a third display panel provided by an embodiment of the present application.

FIG. 6 is a schematic plan view of a display panel provided by an embodiment of the present application.

### DETAILED DESCRIPTION

Each of the following embodiments is described with reference to the accompanying drawings to illustrate a specific embodiment in which the present application may be implemented. Directional terms mentioned in the application, such as “upper”, “lower”, “front”, “rear”, “left”, “right”, “inner”, “outer”, “lateral”, etc. are merely directions with reference to the accompanying drawings. Therefore, the directional terms used are intended to illustrate and understand the present application, rather than to limit it. In the drawings, units with similar structures are represented by the same numbers.

The present application will be further described below in conjunction with the accompanying drawings and specific embodiments:

Embodiments of the present application provide a display panel capable of improving light emission efficiency of the display panel while achieving an anti-peep effect.

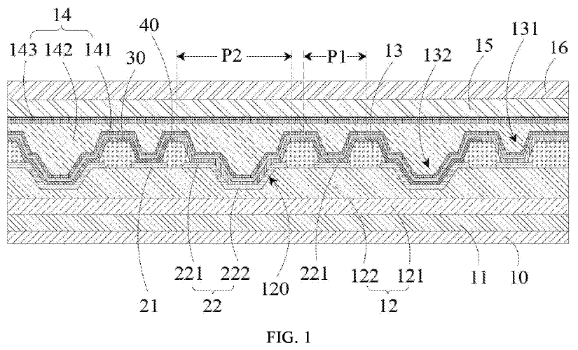

As shown in FIG. 1, the display panel includes a plurality of main pixel regions P1 and a plurality of auxiliary pixel regions P2. The main pixel region P1 and the auxiliary pixel region P2 are arranged adjacent to each other. The display panel includes a substrate 10, a plurality of first anodes 21, a plurality of second anodes 22, a light-emitting layer 30, and a cathode 40. A plurality of the first anodes 21 and a plurality of the second anodes 22 are arranged in an array on the substrate 10. The first anodes 21 are located in the main pixel region P1, and the second anodes 22 are located in the auxiliary pixel region P2. The light-emitting layer 30 is disposed on a side of the first anodes 21 and the second anodes 22 away from the substrate 10. The cathode 40 is disposed on a side of the light-emitting layer 30 away from the substrate 10. Each of the first anodes 21 and the second anodes 22 may form an organic light emitting diode device together with the light emitting layer 30 and the cathode 40.

It should be noted that being disposed on the substrate 10 may mean being in direct contact with the substrate 10, or in indirect contact with the substrate 10.

In the embodiment of the present application, the display panel may further include a drive circuit layer 11, which may be disposed on the substrate 10. The first anodes 21 and the second anodes 22 are disposed on a side of the drive circuit layer 11 away from the substrate 10.

A plurality of pixel driving circuits may be provided in the drive circuit layer 11. Each of the pixel driving circuits may be electrically connected to at least one corresponding first anode 21 or second anode 22 to control and drive a pixel including the first anode 21 or the second anode 22 to emit light.

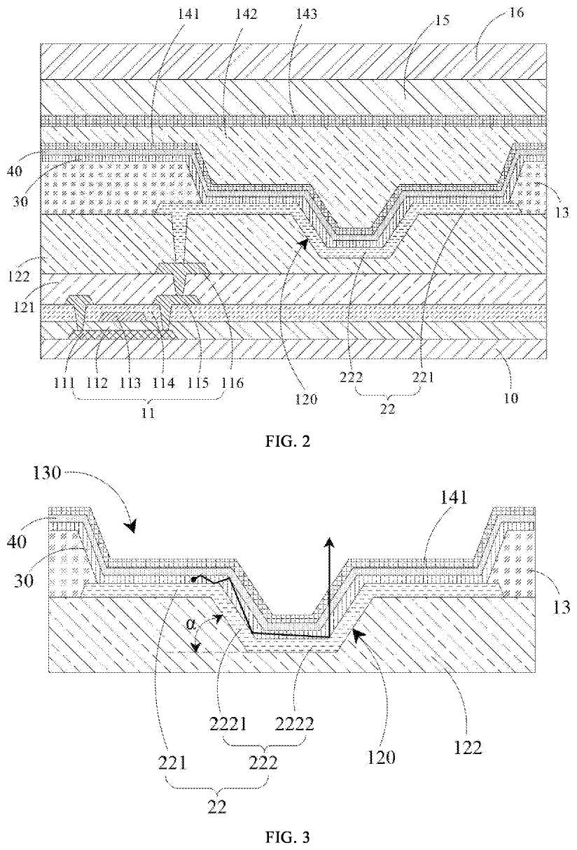

As shown in FIG. 2, the drive circuit layer 11 may include, but is not limited to, an active layer 111, a gate insulating layer 112, a first metal layer 113, an interlayer dielectric layer 114, a second metal layer 115, and a third metal layer 116 that are sequentially stacked on the substrate 10.

A material of the active layer 111 may include, but is not limited to, any one of amorphous silicon, polycrystalline silicon, metal oxide semiconductor material, etc. The first metal layer 113 may also be referred to as a gate metal layer, in which a plurality of patterned gate electrodes and a plurality of scanning lines extending in a lateral direction may be formed.

The second metal layer 115 may also be referred to as a source-drain electrode metal layer. In the second metal layer 115, a plurality of patterned source electrodes and drain electrodes, and a plurality of data lines extending in a vertical direction may be formed. The source electrodes and the drain electrodes may be in contact with the active layer 111 through the interlayer dielectric layer 114 and the gate insulating layer 112, respectively. A plurality of conductive electrodes may be formed in the third metal layer 116. The source electrodes or the drain electrode may be electrically connected to the first anodes 21 or the second anodes 22 through the conductive electrode.

Materials of the first metal layer 113, the second metal layer 115, and the third metal layer 116 are all metals, such as a single-layer or multi-layer structure formed of copper, aluminum, titanium, or molybdenum, etc. The materials of the gate insulating layer 112 and the interlayer dielectric layer 114 may be, but is not limited to, at least one of silicon nitride, silicon oxide, or silicon oxynitride.

It should be noted that the layer structure of the drive circuit layer 11 is described only by taking the example shown in FIG. 2 as an example. In practical applications, the layer structure of the drive circuit layer 11 may be changed according to needs, and is not limited to the layer structure of the drive circuit layer 11 shown in FIG. 2.

In the embodiment of the present application, the type of the organic light-emitting diode device in the display panel is a top-emission type. Each of the first anodes 21 and the second anodes 22 may be formed of an opaque conductive material with high reflectivity, or the first anode 21 and the second anode 22 may be a stacked structure formed of a transparent conductive material and an opaque conductive material with high reflectivity.

For example, each of the first anode 21 and the second anode 22 may include a transparent electrode layer and a reflective electrode layer. The reflective electrode layer is disposed between the transparent electrode layer and the light-emitting layer. The material of the transparent electrode layer may be a transparent and conductive metal oxide, such as indium tin oxide (ITO) or oxide, and the material of the reflective electrode layer may be a metal with high reflectivity, such as aluminum, silver, or nickel.

The light-emitting layer 30 may include, but is not limited to, a hole injection layer, a hole transport layer, an organic light-emitting material layer, an electron transport layer, and an electron injection layer provided in a stack. The organic light-emitting material layer may only be formed in regions respectively defined by pixel openings 130. The hole injection layer, the hole transport layer, the electron transport layer, and the electron injection layer may entirely cover the pixel definition layer 13, or may be formed only in the regions respectively defined by pixel openings 130, without limitation herein. The cathode 40 may entirely cover the light-emitting layer 30 and the pixel definition layer 13.

Further, at least a part of the second anode 22 includes a flat portion 221 and a recessed portion 222, wherein the flat portion 221 is connected to the recessed portion 222.

As shown in FIG. 1, the first anodes 21 is disposed above the substrate 10, and the second anode 22 includes the flat portion 221 and the recessed portion 222. At the first anode 21, the light-emitting layer 30 is in contact with the first anode 21. At the second anode 22, the light-emitting layer 30 is in contact with the recessed portion 222 and at least a part of the flat portion 221.

In the embodiment of the present application, the display panel includes a flat layer 12 disposed between the second anodes 22 and the substrate 10. A side of the flat layer 12 away from the substrate 10 is provided with grooves 120. The flat portion 221 is provided on a periphery of the groove 120, and the recessed portion 222 is laid on a surface of the groove 120.

As shown in FIG. 2, the grooves 120 may be formed on the side surface of the flat layer 12 away from the substrate 10 by a dry etching method, and then the second anodes 22 may be deposited on the flat layer 12 by physical vapor deposition or other methods. The flat portion 221 arranged in a tiled manner is formed at the peripheral edges of the groove 120, and the recessed portion 222 having the same or similar shape as the groove 120 is formed at the groove 120. The recessed portion 222 and the flat portion 221 form an integral structure.

Further, both the light-emitting layer 30 and the cathode 40 have a recessed shape at the recessed portion 222.

As shown in FIG. 3, at the recessed portion 222, both the light-emitting layer 30 and the cathode 40 are recessed into the recessed portion 222 and present a recessed shape. As shown by the arrow in FIG. 3, the light emitted by the light-emitting layer 30 disposed on the flat portion 221 is reflected by the recessed portion 222 and the cathode 40 for a plurality of times. The propagation path and the direction of the light inside the organic light emitting diode device can be changed, so that a part of the light inside the organic light emitting diode device can be emitted into the air, which can improve the light emission efficiency of the organic light emitting diode device. When the display panel is in operation, the main pixel region P1 can emit light normally, the recessed portion 222 of the second anode 22 in the auxiliary pixel region P2 can deflect the light in a direction of a smaller angle, which accelerates the brightness attenuation at a large viewing angle. When the white light is finally synthesized, an abnormal color shift will occur, resulting in distortion, thereby achieving the anti-peep effect while improving the light emission efficiency of the display panel.

In an embodiment, the flat layer 12 includes a first flat layer 121 and a second flat layer 122. The second flat layer 122 is disposed on a side of the first flat layer 121 away from the substrate 10. The second metal layer 115 is disposed on a side of the first flat layer 121 away from the substrate 10. The third metal layer 116 is disposed on a side of the second flat layer 122 away from the substrate 10. The groove 120 is recessed into the second flat layer 122 by a side surface of the second flat layer 122 away from the substrate 10, and does not penetrate the second flat layer 122. That means, the thickness of the groove 120 is smaller than the thickness of the second flat layer 122. The second anode 22 is in contact with the conductive electrode in the third metal layer 116 through a via hole on the second flat layer 122. A portion of the second anode 22 in contact with the third metal layer 116 is disposed offset from the recessed portion 222 and is not in contact with the light-emitting layer 30.

In some other embodiments, the depth of the groove 120 may be set according to the requirements of the light deflection angle. For example, the groove 120 can only penetrate the second flat layer 122 and expose a side surface of the first flat layer 121 close to the second flat layer 122. Alternatively, the groove 120 can also be further recessed into the first flat layer 121 while penetrating the second flat layer 122, so that the propagation path of light in the organic light emitting diode device can also be changed, and the technical effect of light emission efficiency of the display panel can be improved.

Further, the recessed portion 222 has an inclined portion 2221 and a bottom portion 2222, and an angle between the inclined portion and a plane, on which the bottom portion is located, is between 20 degrees and 60 degrees.

As shown in FIG. 2, the cross-sectional shape of the groove 120 is an inverted trapezoid, and the width of the groove 120 gradually decreases from one end away from the substrate 10 to one end close to the substrate 10. The bottom portion 2222 of the second anode 22 is provided on the bottom surface of the groove 120, and the inclined portion 2221 is provided on the side wall of the groove 120. Both the bottom portion 2222 and the inclined portion 2221 have a flat surface. An angle a is formed between the inclined portion 2221 provided obliquely and the plane on which the horizontally provided bottom portion 2222 is located. The angle a can be, but is not limited to, any one of 20 degrees, 30 degrees, 40 degrees, 50 degrees, 60 degrees, and the like. In this way, the side wall of the recessed portion 222 can be used to deflect the light in a direction of a smaller angle, and the brightness attenuation at a large viewing angle can be accelerated. When the white light is finally synthesized, an abnormal color shift will occur, resulting in distortion, thereby achieving the anti-peep effect while improving the light emission efficiency of the display panel.

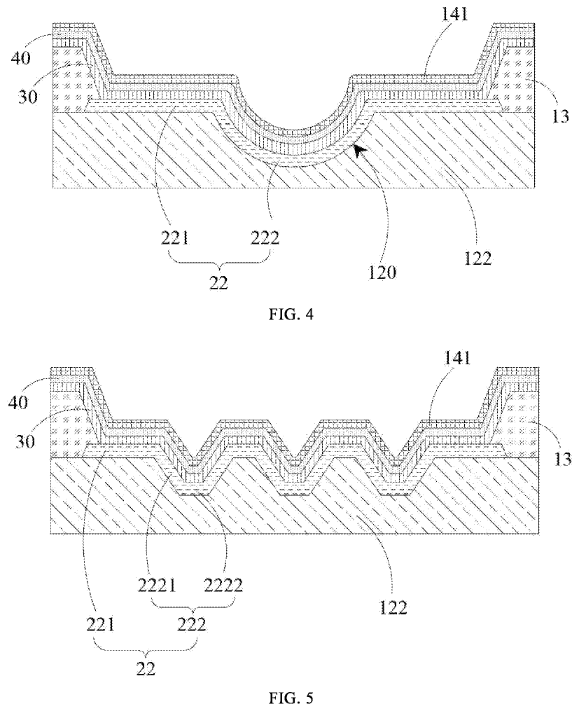

In one embodiment, as shown in FIG. 4, the cross-sectional shape of the groove 120 is an arc shape, the recessed portion 222 of the second anode 22 is the same arc shape as the groove 120, and the angle between the tangent line of any point on the recessed portion 222 and the plane on which the substrate 10 is located should be less than or equal to 60 degrees. It can improve the light emission efficiency of the display panel, and at the same time, deflect the light in a direction of a smaller angle to accelerate the brightness attenuation of the large viewing angle. It not only improves the light emission efficiency of the display panel, but also achieves the anti-peep effect.

In one embodiment, as shown in FIGS. 1 to 4, the second anode 22 may have only one recessed portion 222.

In one embodiment, as shown in FIG. 5, the second anode 22 may have a plurality of recessed portions 222 at the same time. The plurality of recessed portions 222 may be arranged at intervals from each other, and neighboring recessed portions 222 may be connected to each other through a flat portion 221. The plurality of recessed portions 222 may also be arranged continuously. The light-emitting layer 30 and the cathode 40 may form a plurality of recessed structures at the second anode 22.

In one embodiment, the first anode 21 is disposed in the same layer as the second anode 22.

As shown in FIG. 1, the first anode 21 and the second anode 22 are both disposed on the side of the second flat layer 122 away from the substrate 10. The first anode 21 is tiled on the surface of the second flat layer 122 away from the substrate 10. The first anode 21 and the second anode 22 may be made of the same layer of metal material.

Further, the display panel further includes a pixel definition layer 13, which is disposed between the second anode 22 and the light-emitting layer 30. A plurality of first pixel openings 130 are provided on the pixel definition layer 13, and the pixel openings 130 expose the recessed portion 222 and at least the part of the flat portion 221.

As shown in FIG. 1, the pixel definition layer 13 is provided with a plurality of first pixel openings 131 and a plurality of second pixel openings 132. Both of the first pixel openings 131 and the second pixel openings 132 penetrate the pixel definition layer 13. The first pixel opening 131 exposes a part of the first anode 21. The part of the first anode 21 exposed by the first pixel opening 131 is tiled on the substrate 10. Specifically, the part of the first anode 21 exposed by the first pixel opening 131 is tiled on the surface of the second flat layer 122 away from the substrate 10.

The second pixel opening 132 exposes the recessed portion 222 of the second anode 22 and a partial region of the flat portion 221 close to the recessed portion 222. The pixel definition layer 13 covers the partial region of the flat portion 221 away from the recessed portion 222.

Further, an orthographic projection of the recessed portion 222 on the substrate 10 falls within an orthographic projection of the second pixel opening 132 on the substrate 10.

As shown in FIG. 3, the width of the second pixel opening 132 gradually decreases from one end away from the substrate 10 to one end close to the substrate 10, and the width of the recessed portion 222 gradually decreases from one end away from the substrate 10 to one end close to the substrate 10. The minimum width of the second pixel opening 132 is greater than the maximum width of the recessed portion 222, so as to achieve the scheme that the orthographic projection of the recessed portion 222 on the substrate 10 can fall within the orthographic projection of the second pixel opening 132 on the substrate 10, so that the second pixel opening 132 can expose the part of the flat portion 221 and the light-emitting layer 30 can be in contact with the flat portion 221 and the recessed portion 222 at the same time.

In one embodiment, the display panel includes the plurality of main pixel regions P1 and the plurality of auxiliary pixel regions P2. The main pixel regions P1 and the auxiliary pixel regions P2 are alternately arranged, and the main pixel regions P1 and the auxiliary pixel regions P2 may be spaced apart by the pixel definition layer 13.

The first anode 21 is located in the main pixel region P1. One or more of the first anodes 21 may be provided in the same main pixel region P1. Each of the main pixel regions P1 corresponds to one main pixel. The second anode 22 is located in the auxiliary pixel region P2. One or more of the second anodes 22 may be provided in the same auxiliary pixel region P2. Each of the auxiliary pixel regions P2 corresponds to one auxiliary pixel.

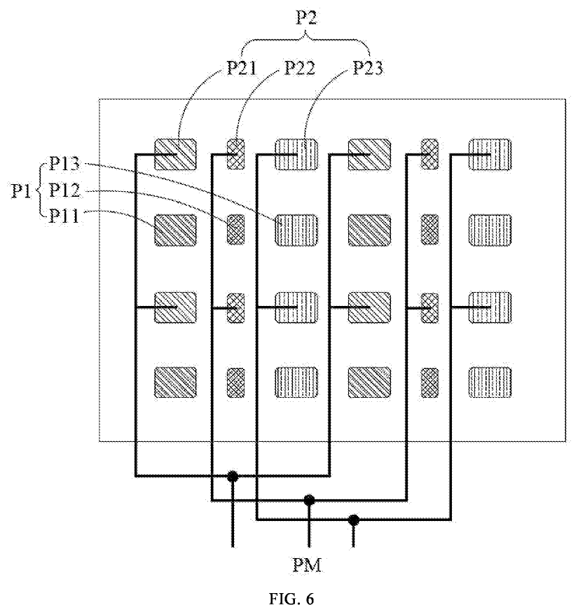

In one of the embodiments, as shown in FIG. 6, the plurality of main pixel regions PI may be arranged in the same row, and the plurality of auxiliary pixel regions P2 may be arranged in the same row. The pixel row in which the main pixel regions P1 are located and the pixel row in which the auxiliary pixel regions P2 are located may be alternately and repeatedly arranged in sequence along the column direction, so that the light emission efficiency of the display panel can be improved, anti-peep effect can be achieved, and the uniformity of brightness and color cast of the entire display panel can be ensured.

In some other embodiments, the plurality of main pixel regions P1 may be arranged in the same column, and the plurality of auxiliary pixel regions P2 may be arranged in the same column. The pixel column in which the main pixel regions P1 are located and the pixel column in which the auxiliary pixel regions P2 are located may be alternately and repeatedly arranged in sequence along the row direction. Alternatively, the main pixel region P1 and the auxiliary pixel region P2 may also be provided in the same row or column at the same time, so that the light emission efficiency of the display panel can be improved, the anti-peep effect can be achieved, and the brightness and color cast uniformity of the entire display panel can be ensured.

As illustrated in FIG. 6, the main pixel region PI may include a first main pixel region P11, a second main pixel region P12, and a third main pixel region P13. The first main pixel region P11, the second main pixel region P12, and The third main pixel region P13 emit light in different colors, and can respectively emit one of red, blue, and green. The auxiliary pixel region P2 may include a first auxiliary pixel region P21, a second auxiliary pixel region P22, and a third auxiliary pixel region P23. The first auxiliary pixel region P21, the second auxiliary pixel region P22, and the third auxiliary pixel region P23 emit light in different colors, and can respectively emit one of red, blue, and green.

In one embodiment, when displaying any frame of the picture, at least the part of the main pixel region P1 and at least the part of the auxiliary pixel region P2 emit light simultaneously. When displaying any frame of picture, the main pixel region P1 and the auxiliary pixel region P2 can be light up at the same time. The brightness attenuation at each angle of the main pixel region P1 is balanced, the light of the auxiliary pixel region P2 is deflected in a direction of smaller angle, and the brightness in the positive viewing angle direction is increased, all of which can improve the light emission efficiency of the display panel, at the same time, accelerate the brightness attenuation at large angles, and achieve the anti-peep effect.

Further, the number of the main pixel regions PI and the number of the auxiliary pixel regions P2 are the same, so that the uniformity of brightness and color cast of the entire display panel can be ensured.

In one embodiment, the display panel has an anti-peep mode and a normal display mode. When the display panel is in the normal display mode, the auxiliary pixel region P2 does not emit light. When the display panel is in the anti-peep mode, at least the part of the auxiliary pixel regions P2 and the corresponding main pixel regions emit light simultaneously.

Compared with the present embodiment, the display panel provided in the previous embodiment does not need to operate in the anti-peep mode. When a normal screen is displayed, the auxiliary pixel regions P2 and the corresponding main pixel regions P1 can emit light simultaneously, meanwhile, the display panel can have the anti-peep effect. The display panel provided by the present embodiment is provided with the normal display mode and the anti-peep mode. When the display panel is in the normal display mode, only the main pixel regions P1 emit light, the auxiliary pixel regions P2 does not emit light, and the brightness at each angle of the display panel changes uniformly, so that the best display effect can be achieved. When the display panel is in the anti-peep mode, at least part of the auxiliary pixel regions P2 and the corresponding main pixel regions P1 emit light simultaneously.

It should be noted that after the anti-peep mode is turned on, the main pixel regions P1 and the auxiliary pixel regions P2 can emit light at the same time. The light emitted from the auxiliary pixel region P2 is deflected in a direction of a smaller angle by the influence of the recessed portion 222, and the attenuation of brightness at a large angle is accelerated. When white light is finally synthesized, color shift abnormality occurs, resulting in distortion, and the peeping prevention effect is realized.

Further, the display panel includes a first pixel driving circuit electrically connected to the first anode, and a second pixel driving circuit electrically connected to the second anode. The first pixel driving circuit is an active matrix circuit, and the second pixel driving circuit is an active matrix circuit or a passive matrix circuit.

In one embodiment, the first pixel driving circuit is an active matrix circuit, and the second pixel driving circuit PM is an active matrix circuit. That means, both the main pixel region P1 and the auxiliary pixel region P2 are controlled by the active matrix circuit.

In one embodiment, the first pixel driving circuit is an active matrix circuit, and the second pixel driving circuit PM is a passive matrix circuit. Compared with using an active matrix circuit to control the main pixel region P1 and the auxiliary pixel region P2, using the passive matrix circuit to control the auxiliary pixel region P2 can reduce the number of thin film transistors in the drive circuit layer 11, thereby simplifying the structure of the display panel and reducing the difficulty of controlling the auxiliary pixel region P2.

Further, as shown in FIG. 1, the display panel may further include an encapsulation layer 14. The encapsulation layer 14 may be a thin film encapsulation structure including a first inorganic encapsulation layer 141, an organic encapsulation layer 142, and a second inorganic encapsulation layer 143 that are stacked. In practical applications, the structure of the encapsulation layer 14 is not limited to the thin film encapsulation structure in the above-described embodiment. The encapsulation layer 14 may be a single-layer or multi-layer encapsulation structure formed of an inorganic material, which is not limited here.

Further, as described in FIG. 1, the display panel may further include an adhesive layer 15 and a barrier film 16. The adhesive layer 15 is provided between the barrier film 16 and the encapsulation layer 14.

Beneficial effects of embodiments of the present application: embodiments of the present application provide a display panel, wherein the display panel includes a plurality of main pixel regions and a plurality of auxiliary pixel regions. The main pixel region is adjacent to the auxiliary pixel region. The display panel further includes a substrate, the plurality of first anodes, a plurality of second anodes, a light-emitting layer and a cathode. The first anodes are located in the main pixel region, and the second anodes are located in the auxiliary pixel region. The second anode includes a flat portion and a recessed portion, wherein the flat portion is connected to the recessed portion. The light-emitting layer is disposed on the side of the first anode and the second anode away from the substrate. The portion of the first anode in contact with the light-emitting layer is tiled on the substrate, and the light-emitting layer is in contact with the recessed portion and at least a portion of the flat portion. When the display panel is working, the main pixel regions can emit light normally, the recessed portion of the second anode in the auxiliary pixel regions can deflect the light in a direction of smaller angle, and the brightness attenuation at a large viewing angle can accelerate, thereby achieving an anti-peep effect and improving the light extraction efficiency of the display panel.

According to the display panel provided by the above embodiments of the present application, the embodiments of the present application further provide a display device including a motherboard, a frame, and a display panel, wherein the motherboard is provided in the frame, the display panel is fixedly provided on the frame, and the motherboard and the display panel are electrically connected. The display panel of the display device may be the display panel provided by any of the above embodiments, and the structure of the display panel will be omitted.

In summary, although the present application is disclosed as above with preferred embodiments, the above embodiments are not intended to limit the present application. Those skilled in the art can make various changes and modifications without departing from the spirit and scope of the present application. Therefore, the scope of protection of the present application is based on the scope defined by the claims.

What is claimed is:

1. A display panel comprising a plurality of main pixel regions and a plurality of auxiliary pixel regions, the main pixel region being disposed adjacent to the auxiliary pixel region, and the display panel further comprising:
a substrate;
a plurality of first anodes disposed on the substrate, the first anodes being located in the main pixel regions;
a plurality of second anodes disposed on the substrate, the second anodes being located in the auxiliary pixel regions, the second anodes comprising a flat portion and a recessed portion, and the recessed portion being connected to the flat portion;
a light-emitting layer disposed on a side of the first anode and the second anode away from the substrate, the light-emitting layer being in contact with the first anode, and the light-emitting layer being in contact with the recessed portion and at least a part of the flat portion; and
a cathode disposed on a side of the light-emitting layer away from the substrate.

2. The display panel according to claim 1, wherein the display panel comprises an anti-peep mode and a normal display mode;
when the display panel is in the anti-peeping mode, at least a part of the auxiliary pixel regions and the corresponding main pixel regions emit light simultaneously; and
when the display panel is in the normal display mode, the auxiliary pixel regions do not emit light.

3. The display panel according to claim 2, wherein the display panel comprises a first pixel driving circuit electrically connected to the first anodes, and a second pixel driving circuit electrically connected to the second anodes; and
wherein the first pixel driving circuit is an active matrix circuit, and the second pixel driving circuit is an active matrix circuit or a passive matrix circuit.

4. The display panel according to claim 1, wherein the display panel comprises a flat layer, and the flat layer is disposed between the second anodes and the substrate;
wherein a side of the flat layer away from the substrate is provided with grooves, the flat portion is laid on a periphery of the groove, and the recessed portion is laid on a surface of the groove.

5. The display panel according to claim 4, wherein a width of the groove gradually decreases from one end away from the substrate to one end close to the substrate.

6. The display panel according to claim 4, wherein a cross-sectional shape of the groove is an inverted trapezoid.

7. The display panel according to claim 4, wherein the flat layer comprises a first flat layer and a second flat layer, and the second flat layer is disposed on a side of the first flat layer away from the substrate; and
wherein the groove is recessed into the second flat layer from a side surface of the second flat layer away from the substrate, and a thickness of the groove is less than or equal to a thickness of the second flat layer.

8. The display panel according to claim 4, wherein the recessed portion has an inclined portion and a bottom portion, and an angle between the inclined portion and a plane, on which the bottom portion is located, is between 20 degrees and 60 degrees.

9. The display panel according to claim 1, wherein the display panel further comprises a pixel definition layer, and the pixel definition layer is disposed between the anode and the light emitting layer; and
wherein a plurality of first pixel openings and a plurality of second pixel openings are provided on the pixel definition layer, a portion of the first anode exposed by the first pixel opening is tiled on the substrate, and the second pixel opening exposes the recessed portion and at least a portion of the flat portion.

10. The display panel according to claim 8, wherein an orthographic projection of the recessed portion on the substrate falls within an orthographic projection of the second pixel opening on the substrate.

11. The display panel according to claim 1, wherein the main pixel regions and the auxiliary pixel regions are alternately disposed, and the first anode and the second anode are disposed in a same layer.

12. The display panel according to claim 1, wherein a number of the main pixel regions and a number of the auxiliary pixel regions are the same.

13. A display device, comprising a display panel comprising a plurality of main pixel regions and a plurality of auxiliary pixel regions, the main pixel region being disposed adjacent to the auxiliary pixel region, and the display panel further comprising:
a substrate;
a plurality of first anodes disposed on the substrate, the first anodes being located in the main pixel regions;
a plurality of second anodes disposed on the substrate, the second anodes being located in the auxiliary pixel regions, the second anodes comprising a flat portion and a recessed portion, and the recessed portion being connected to the flat portion;
a light-emitting layer disposed on a side of the first anode and the second anode away from the substrate, the light-emitting layer being in contact with the first anode, and the light-emitting layer being in contact with the recessed portion and at least a part of the flat portion; and
a cathode disposed on a side of the light-emitting layer away from the substrate.

14. The display device according to claim 13, wherein the display panel comprises an anti-peep mode and a normal display mode;
when the display panel is in the anti-peeping mode, at least a part of the auxiliary pixel regions and the corresponding main pixel regions emit light simultaneously; and
when the display panel is in the normal display mode, the auxiliary pixel regions do not emit light.

15. The display device according to claim 14, wherein the display panel comprises a first pixel driving circuit electrically connected to the first anodes, and a second pixel driving circuit electrically connected to the second anodes;
wherein the first pixel driving circuit is an active matrix circuit, and the second pixel driving circuit is an active matrix circuit or a passive matrix circuit.

16. The display device according to claim 13, wherein the display panel comprises a flat layer, and the flat layer is disposed between the second anodes and the substrate;
wherein a side of the flat layer away from the substrate is provided with grooves, the flat portion is laid on a periphery of the groove, and the recessed portion is laid on a surface of the groove.

17. The display device according to claim 16, wherein a width of the groove gradually decreases from one end away from the substrate to one end close to the substrate.

18. The display device according to claim 16, wherein a cross-sectional shape of the groove is an inverted trapezoid.

19. The display device according to claim 16, wherein the flat layer comprises a first flat layer and a second flat layer, and the second flat layer is disposed on a side of the first flat layer away from the substrate; and
wherein the groove is recessed into the second flat layer from a side surface of the second flat layer away from the substrate, and a thickness of the groove is less than or equal to a thickness of the second flat layer.

20. The display device according to claim 16, wherein the recessed portion has an inclined portion and a bottom portion, and an angle between the inclined portion and a plane, on which the bottom portion is located, is between 20 degrees and 60 degrees.
